(19) United States
(12) Patent Application Publication
(10) Pub. No.: US 2011/0309890 A1
(43) Pub. Date: Dec. 22, 2011

(54) OSCILLATOR AND ELECTRONIC DEVICE

(75) Inventor: Manabu Miura, Kanagawa-ken (JP)

(73) Assignee: KABUSHIKI KAISHA TOSHIBA, Tokyo (JP)

(21) Appl. No.: 13/109,240

(22) Filed: May 17, 2011

(30) Foreign Application Priority Data
Jun. 16, 2010 (JP) 2010-137069

(51) Int. Cl. H03B 5/12

(52) U.S. Cl. 331/117 FE; 331/108 R

(57) ABSTRACT

According to one embodiment, an oscillator includes a resonant circuit and an amplifier circuit. The resonant circuit includes one end, one other end, and a frequency correction circuit. The amplifier circuit is connected in parallel with the resonant circuit. The amplifier circuit is configured to amplify a signal at the one end and to output to the one other end. The frequency correction circuit includes a first capacitor and a first transistor connected in series with the first capacitor so that potentials of both ends of the first transistor are variable.

### CROSS-REFERENCE TO RELATED APPLICATIONS

This application is based upon and claims the benefit of priority from the prior Japanese Patent Application No. 2010-137069, filed on Jun. 16, 2010; the entire contents of which are incorporated herein by reference.

### FIELD

Embodiments described herein relate generally to an oscillator and an electronic device.

### BACKGROUND

Various oscillators are used in multifunctional electronic devices. An oscillator based on an LC resonant circuit can be integrated in a semiconductor substrate and is suitable for downsizing. However, variations in its circuit constants due to the manufacturing process cause fluctuations in oscillation frequency. Hence, it is required that a frequency correction circuit corrects the resonant frequency.

Furthermore, electronic devices with power saving features are often equipped with a sleep mode for disconnecting the power supply to stop the operation when not in use.

However, the frequency correction circuit may prolong the time required for the oscillation frequency to be stabilized after start-up. Thus, the sleep mode cannot be used in the case of requiring fast response. This presumably has an adverse effect on the power saving of electronic devices.

### BRIEF DESCRIPTION OF THE DRAWINGS

FIG. 1 is a circuit diagram illustrating a configuration of an oscillator according to a first embodiment;

FIG. 2 is a circuit diagram of a frequency correction circuit of an analysis example;

FIG. 3 is a waveform diagram of terminal voltages of a transistor of the frequency correction circuit of the analysis example;

FIG. 4 is a waveform diagram in which the time axis of the waveform diagram shown in FIG. 3 is scaled up;

FIG. 5 is a waveform diagram of the back gate current of the transistor of the frequency correction circuit of the analysis example;

FIG. 6 is a characteristic diagram showing the oscillation frequency of the oscillator of the analysis example;

FIG. 7 is a waveform diagram of terminal voltages of the first transistor of the frequency correction circuit shown in FIG. 1;

FIG. 8 is a waveform diagram in which the time axis of the waveform diagram shown in FIG. 7 is scaled up;

FIG. 9 is a waveform diagram of the back gate current of the first transistor of the frequency correction circuit shown in FIG. 1;

FIG. 10 is a characteristic diagram showing the oscillation frequency of the oscillator shown in FIG. 1; and

FIG. 11 is a circuit diagram illustrating a configuration of an electronic device according to a second embodiment.

### DETAILED DESCRIPTION

In general, according to one embodiment, an oscillator includes a resonant circuit and an amplifier circuit. The resonant circuit includes one end, one other end, and a frequency correction circuit. The amplifier circuit is connected in parallel with the resonant circuit. The amplifier circuit is configured to amplify a signal at the one end and to output to the one other end. The frequency correction circuit includes a first capacitor and a first transistor connected in series with the first capacitor so that potentials of both ends of the first transistor are variable.

Various embodiments will be described hereinafter with reference to the accompanying drawings. In the present specification and the drawings, components similar to those described previously with reference to earlier figures are labeled with like reference numerals, and the detailed description thereof is omitted as appropriate.

### First Embodiment

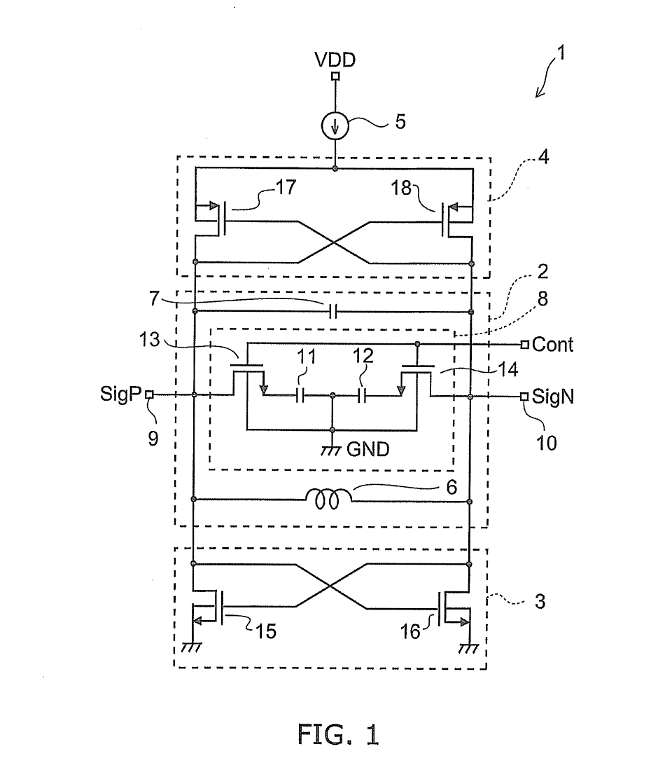

FIG. 1 is a circuit diagram illustrating a configuration of an oscillator according to a first embodiment.

As shown in FIG. 1, the oscillator 1 includes a resonant circuit 2, amplifier circuits 3, 4, and a constant current circuit 5. These are formed in the same semiconductor substrate to have a one-chip structure.

The resonant circuit 2 includes an inductor 6, a resonant capacitor 7, and a frequency correction circuit 8. The inductor 6, the resonant capacitor 7, and the frequency correction circuit 8 are connected parallel to each other between both ends 9, 10 of the resonant circuit 2. The resonant circuit 2 is an LC parallel resonant circuit. The resonant frequency of the resonant circuit 2 defines the oscillation frequency of the oscillator 1.

The inductor 6 can be e.g. a spiral inductor provided on the semiconductor substrate. The resonant capacitor 7 can be e.g. a parallel plate capacitor having a metal-insulator-metal (MIM) structure in which an insulating film is sandwiched as a dielectric between metal electrodes.

The frequency correction circuit 8 includes a pair of first capacitors 11, 12 and a pair of first transistors 13, 14.

One end of the first capacitor 11 is connected to the ground GND. The first transistor 13 is connected between the other end of the first capacitor 11 and one end 9 of the resonant circuit 2. One end of the first capacitor 12 is connected to the ground GND. The first transistor 14 is connected between the other end of the first capacitor 12 and the other end 10 of the resonant circuit 2. The potentials of both ends of each of the first transistors 13, 14 are variable and not fixed alternatingly.

Like the resonant capacitor 7, the first capacitors 11, 12 can be capacitors having an MIM structure. The first transistors 13, 14 are each configured as an n-channel MOSFET (hereinafter NMOS).

The back gates of the first transistors 13, 14 are both connected to the ground GND. A high level or low level control signal Cont is inputted to the gate.

Here, the high level is a gate voltage at which the first transistors 13, 14 are placed in the conduction state and the on-resistance thereof decreases to a sufficiently small value. For instance, the high level is a power supply voltage VDD. The low level is a gate voltage at which the first transistors 13, 14 are placed in the cutoff state and can sufficiently maintain the drain-source cutoff state. For instance, the low level is the ground potential.

When the control signal Cont is at the low level, the first transistors 13, 14 are placed in the cutoff state. The first capacitors 11, 12 are disconnected from both ends 9, 10 of the resonant circuit 2. At this time, the capacitance between both ends 9, 10 of the resonant circuit 2 is the combined capacitance of the capacitance of the resonant capacitor 7 and the parasitic capacitances of the inductor 6 and the transistors 15-18 of the amplifier circuits 3, 4.

When the control signal Cont is at the high level, the first transistors 13, 14 are placed in the conduction state. The first capacitors 11, 12 of the frequency correction circuit 8 are connected to both ends 9, 10 of the resonant circuit 2, respectively. At this time, the capacitance between both ends 9, 10 of the resonant circuit 2 is the combined capacitance of the capacitance for the low level control signal Cont and the capacitances of the first capacitors 11, 12.

Thus, by changing the capacitance value of the frequency correction circuit 8 using the control signal Cont, the capacitance between both ends 9, 10 of the resonant circuit 2 can be changed. This can correct the variations in resonant frequency caused by variations of parameters such as the inductance of the inductor 6 and the capacitance of the resonant capacitor 7 due to the manufacturing process. Thus, the oscillation frequency of the oscillator 1 can be corrected.

For instance, while changing the level of the control signal Cont, the oscillation frequency of the oscillator 1 is measured. Thus, the level of the control signal Cont minimizing the error from the defined value can be determined. Furthermore, for instance, the oscillator 1 can be provided with a nonvolatile memory to store the level of the control signal Cont minimizing the error. Then, when the oscillator 1 is operated, the level of the control signal Cont can be read from the nonvolatile memory and set as the control signal Cont to correct the oscillation frequency of the oscillator 1.

The drains of the first transistors 13, 14 are placed at the voltage of both ends 9, 10 of the resonant circuit 2, and thus each biased at a DC voltage of approximately half the power supply voltage VDD. The potential of the drains of the first transistors 13, 14 varies with the oscillation output during the oscillating operation of the oscillator 1. The potential of the drains of the first transistors 13, 14 varies around the bias DC potential, and is not fixed alternatingly. The potential of the sources of the first transistors 13, 14 is not fixed directly and alternatingly. The potential of the sources of the first transistors 13, 14 varies with the oscillation output of the oscillator 1.

Thus, the potential of both ends, i.e., drain and source, of the first transistors 13, 14 varies with the signal at both ends 9, 10 of the resonant circuit 2 during the oscillating operation, and is not fixed alternatingly. As described later, this can reduce the time required for the oscillation frequency to be stabilized.

The amplifier circuit 3 includes transistors 15, 16.

The transistors 15, 16 are NMOS. The sources of the transistors 15, 16 are both connected to the ground GND. The drain of the transistor 15 and the gate of the transistor 16 are connected to the one end 9 of the resonant circuit 2. The gate of the transistor 15 and the drain of the transistor 16 are connected to the other end 10 of the resonant circuit 2.

The amplifier circuit 3 is a positive feedback amplifier circuit and connected between both ends 9, 10 of the resonant circuit 2.

Signals at the ends 9, 10 of the resonant circuit 2 are inputted to and amplified by the amplifier circuit 3, and positively fed back (outputted) to the ends 9, 10, respectively. Oscillation occurs at a frequency satisfying the oscillation condition including the impedance between both ends 9, 10 of the resonant circuit 2 and the gain of the amplifier circuit 3.

The amplifier circuit 4 includes transistors 17, 18.

The transistors 17, 18 are p-channel MOSFET (hereinafter PMOS). The sources of the transistors 17, 18 are each supplied with the power supply voltage VDD through the constant current circuit 5. The drain of the transistor 17 and the gate of the transistor 18 are connected to the one end 9 of the resonant circuit 2. The gate of the transistor 17 and the drain of the transistor 18 are connected to the other end 10 of the resonant circuit 2.

The amplifier circuit 4 is a positive feedback amplifier circuit and connected between both ends 9, 10 of the resonant circuit 2.

In the oscillator 1, the amplifier circuits 3, 4 are symmetric with respect to both ends 9, 10 of the resonant circuit 2. The amplifier circuit 4 functions as a load of the amplifier circuit 3. The amplifier circuit 3 functions as a load of the amplifier circuit 4. While the oscillator 1 includes the amplifier circuits 3, 4 in the illustrated configuration, the oscillator 1 may be configured to include only one of the amplifier circuits 3, 4.

The constant current circuit 5 is supplied with the power supply voltage VDD and supplies a current to the amplifier circuits 3, 4.

Next, the operation of the oscillator 1 is described. Upon application of the power supply voltage VDD, a current is supplied to the oscillator 1 through the constant current circuit 5. Then, the transistors 15-18 of the amplifier circuits 3, 4 start amplification operation. At the beginning of operation, when the voltage SigP of the one end 9 of the resonant circuit 2 is higher than the voltage SigN of the other end 10 of the resonant circuit 2, a current flows in the transistor 17. Thus, by voltage drop due to the output impedance of the transistor 17, the voltage SigP of the one end 9 of the resonant circuit 2 changes in the decreasing direction.

Furthermore, a current flows in the transistor 16. By voltage drop due to the output impedance of the transistor 16, the voltage SigN of the other end 10 increases. As a result, the circuit is transferred to the state of SigN>SigP, i.e., the voltage SigN of the other end 10 is higher than the voltage SigP of the one end 9.

When the circuit is placed in the state of the voltage SigN of the other end 10>the voltage SigP of the one end 9, an operation opposite to the above operation occurs. Then, the circuit is transferred to the state of the voltage SigP of the one end 9>the voltage SigN of the other end 10. These operations continue, and oscillation is maintained.

Here, the impedance between both ends 9, 10 of the resonant circuit 2 is maximized at the resonant frequency. Hence, in the above description, the operation of the resonant circuit 2 is omitted.

The oscillator 1 is a multivibrator based on the resonant circuit 2. The oscillation frequency is primarily defined by the resonant frequency of the resonant circuit 2. The resonant frequency can be changed by the frequency correction circuit 8 to adjust the oscillation frequency.

The frequency correction circuit 8 is composed of the first transistors 13, 14 and the first capacitors 11, 12. To stabilize the oscillation frequency, the Q value (quality factor) representing the resonance characteristics of the resonant circuit 2 needs to be made high. Thus, the frequency correction circuit 8 needs to avoid significantly decreasing the Q value of the resonant circuit 2.

For instance, the impedance of the first transistors 13, 14 is set to be 1/10 or less of the impedance of the first capacitors 11, 12, respectively. Thus, when the first transistors 13, 14 are turned on, most of the voltage between both ends 9, 10 of the resonant circuit 2 is applied to the first capacitors 11, 12.

However, when the first transistors 13, 14 are turned off, the impedance of the first transistors 13, 14 is higher than the impedance of the first capacitors 11, 12. That is, the relation of the impedance of the first transistors 13, 14>>the impedance of the first capacitors 11, 12 occurs. Thus, the circuit is placed in the state in which most of the voltage between both ends 9, 10 of the resonant circuit 2 is applied to the first transistors 13, 14.

Here, as shown in FIG. 1, the potential of both ends, i.e., drain and source, of the first transistors 13, 14 of the frequency correction circuit 8 changes with the signal at both ends 9, 10 of the resonant circuit 2. Thus, as described later, it is possible to provide an oscillator in which the time required for the oscillation frequency to be stabilized is short.

The configuration of the oscillator 1 according to the first embodiment has been constructed based on the phenomenon newly found from the analysis result described below.

The inventor studied in detail the operation of the frequency correction circuit in the oscillator.

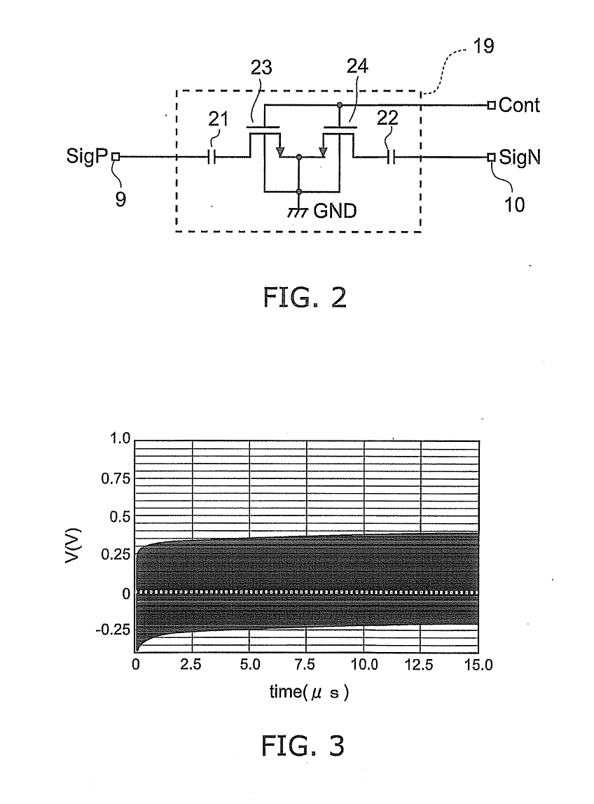

FIG. 2 is a circuit diagram of a frequency correction circuit of an analysis example.

As shown in FIG. 2, in the frequency correction circuit 19 of the analysis example, the source and the back gate of the transistors 23, 24 are connected to the ground GND. A capacitor 21 is connected between the drain of the transistor 23 and one end 9 of the resonant circuit 2. A capacitor 22 is connected between the drain of the transistor 24 and the other end 10 of the resonant circuit 2.

The oscillator of the analysis example is configured by replacing the frequency correction circuit 8 of the resonant circuit 2 of the oscillator 1 shown in FIG. 1 by the frequency correction circuit 19 of the analysis example. The amplifier circuit 3, the load circuit 4, the constant current circuit 5, the inductor 6, and the resonant capacitor 7 are similar to those of the oscillator 1 shown in FIG. 1.

In this analysis, simulation was used to examine the change of the source voltage, drain voltage, back gate current, and oscillation frequency of the transistor 23 from the time of application of the power supply voltage VDD until the oscillation frequency is stabilized. By symmetry, the simulation result is shown with regard to the transistor 23 between the one end 9 of the resonant circuit and the ground GND. The transistors 23, 24 are turned off.

FIG. 3 is a waveform diagram of terminal voltages of a transistor of the frequency correction circuit of the analysis example.

In FIG. 3, the horizontal axis represents time (μs), and the vertical axis represents voltage V. The waveform of the source voltage and the waveform of the drain voltage of the transistor 23 are shown by the dashed line and the solid line, respectively.

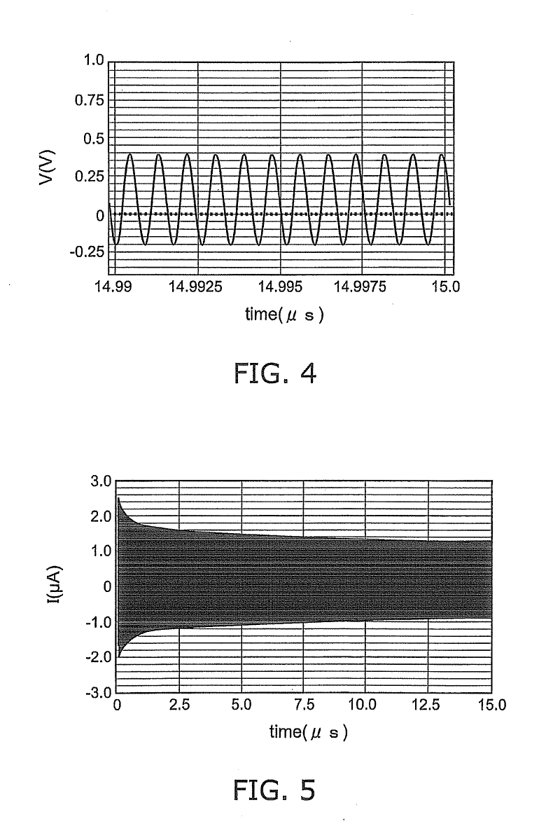

FIG. 4 is a waveform diagram in which the time axis of the waveform diagram shown in FIG. 3 is scaled up. FIG. 4 shows the range on the time axis from time=14.99 μs to 15.0 μs.

FIG. 5 is a waveform diagram of the back gate current of the transistor of the frequency correction circuit of the analysis example.

The source of the transistor 23 is connected to the ground GND. Thus, application of the drain voltage swings to negative, and the voltage between the drain and the back gate greatly swings between reverse and forward. Accordingly, a forward current flows between the drain and the back gate, and the parasitic capacitance also greatly varies. However, the time constant is large due to the parasitic resistance of the diode between the drain and the back gate. This requires a long time to charge the capacitor 21. Hence, a long time is required for the DC component of the drain voltage to reach the steady state. The DC component of the drain voltage determines the capacitance between the drain and the back gate.

For the above reasons, the variation of the oscillation frequency continues until the drain voltage reaches the steady state. It is thus inferred that the oscillation frequency is unstable for a long time.

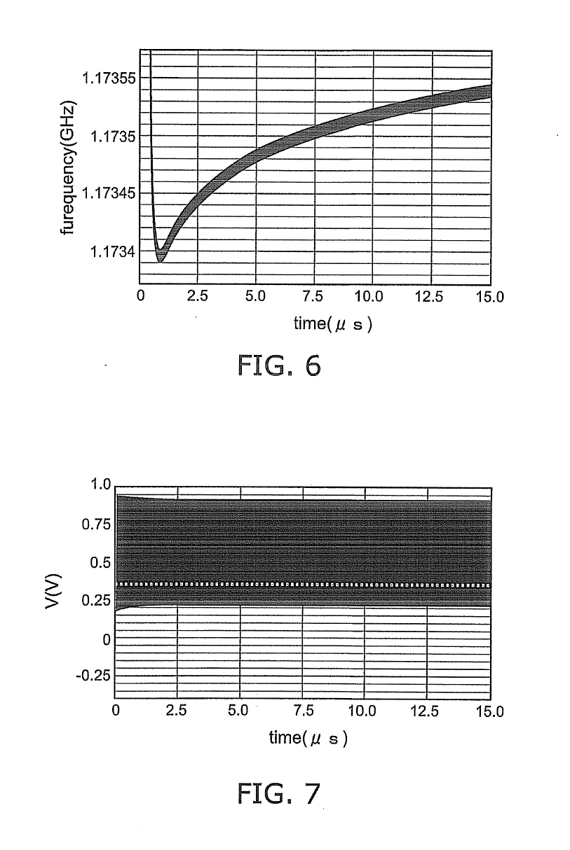

FIG. 6 is a characteristic diagram showing the oscillation frequency of the oscillator of the analysis example.

From the application of the power supply voltage VDD at time=0 μs until the DC component of the drain voltage reaches the steady state, the oscillation frequency varies and remains unstable.

Hence, it is inferred that to reduce the time required for the oscillation frequency to be stabilized, the drain of the transistor needs to be prevented from swinging to negative with respect to the back gate so as to prevent the forward current from flowing between the drain and the back gate.

The above simulation result can be analyzed as follows.

When the one end 9 of the resonant circuit is at the high level, the transistor 15 of the amplifier circuit 3 is turned off. The transistors 23, 24 are turned off, and the frequency correction circuit 19 of the analysis example is turned off.

At this time, the capacitors 21, 22 are DC-decoupled from the ground GND.

With the potential variation of the one end 9 or the other end 10 of the resonant circuit, the capacitors 21, 22 start to repeat charging and discharging. However, if the potential of the one end 9 or the other end 10 decreases to a certain value or less, the impedance of the transistors 15, 16 of the amplifier circuit 3 of the oscillator increases. This prolongs the time constant. Thus, the circuit is transferred to the next state before sufficient charging or discharging.

When the one end 9 (other end 10) is at the high level, the other end 10 side electrode (one end 9 side electrode) of the capacitor 21 (22) is negatively charged. With the potential drop of the one end 9 (other end 10), the capacitor 21 (22) starts to discharge. However, there is only the transistor 23 (24) with the discharge path to the ground GND being turned off. Hence, the drain terminal of the transistor 23 (24) is negatively charged, and causes discharging due to the decrease of the impedance.

The charging cycle and the discharging cycle both occur through a high resistance. This prolongs the charging and discharging time constant.

Hence, it is inferred that to reduce the time required for the oscillation frequency to be stabilized, the capacitors 21, 22 need to be prevented from charging and discharging so that the drain of the transistor does not swing to negative with respect to the back gate. Thus, it is inferred that the forward current needs to be prevented from flowing between the drain and the back gate.

The frequency correction circuit 8 of the oscillator 1 according to the first embodiment is constructed based on the above analysis result. One end of each of the first capacitors 11, 12 is connected to the ground GND. The first transistor 13 is connected between the other end of the first capacitor 11 and one end 9 of the resonant circuit 2. The first transistor 14 is connected between the other end of the first capacitor 12 and the other end 10 of the resonant circuit 2.

The drains of the first transistors 13, 14 are placed at the voltage of both ends 9, 10 of the resonant circuit 2, and thus each biased at approximately half the power supply voltage VDD. The potential of the drains of the first transistors 13, 14 varies with the signal at both ends 9, 10 of the resonant circuit 2 during the oscillating operation of the oscillator 1. The potential of the drains of the first transistors 13, 14 varies around the bias DC potential, and is not fixed alternatingly. The potential of the sources of the first transistors 13, 14 is not fixed directly and alternatingly. The potential of the sources of the first transistors 13, 14 varies with the signal at both ends 9, of the resonant circuit 2 during the oscillating operation of the oscillator 1. The drain of the first transistors 13, 14 does not swing to negative with respect to the back gate.

When the frequency correction circuit 8 is turned off, the first transistors 13, 14 are turned off, and the first capacitors 11, 12 are isolated from the oscillator 1. Hence, the charging and discharging phenomenon as in the frequency correction circuit 19 of the analysis example does not occur.

FIG. 7 is a waveform diagram of terminal voltages of the first transistor of the frequency correction circuit shown in FIG. 1.

In FIG. 7, the horizontal axis represents time (μs), and the vertical axis represents voltage V. The waveform of the source voltage and the waveform of the drain voltage of the first transistor 13 are shown by the dashed line and the solid line, respectively.

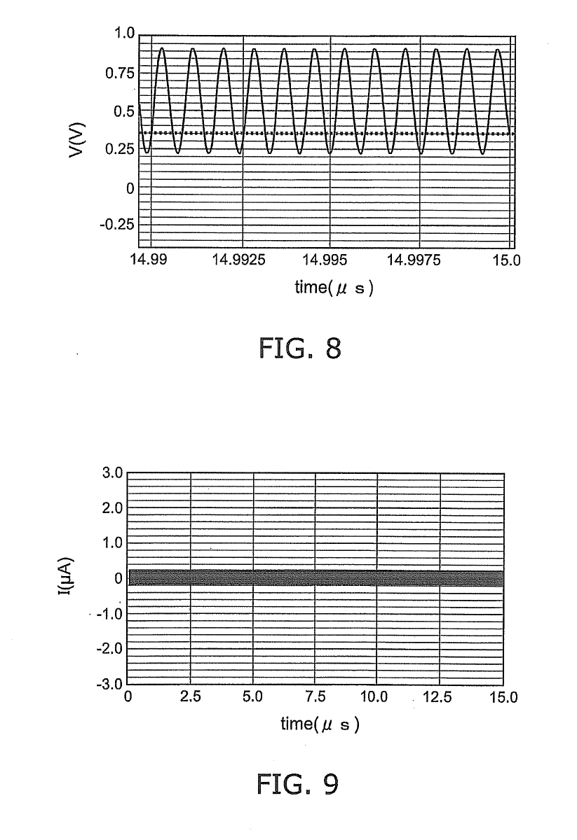

FIG. 8 is a waveform diagram in which the time axis of the waveform diagram shown in FIG. 7 is scaled up. FIG. 8 shows the range on the time axis from time=14.99 μs to 15.0 μs.

FIG. 9 is a waveform diagram of the back gate current of the first transistor of the frequency correction circuit shown in FIG. 1.

The first capacitors 11, 12 are inserted between the source of the first transistors 13, 14 and the ground GND, respectively. This remedies the state in which application of the drain voltage swings to negative. Furthermore, the voltage between the drain and the back gate does not greatly swing between reverse and forward. Hence, no forward current flows between the drain and the back gate, and the parasitic capacitance is stabilized.

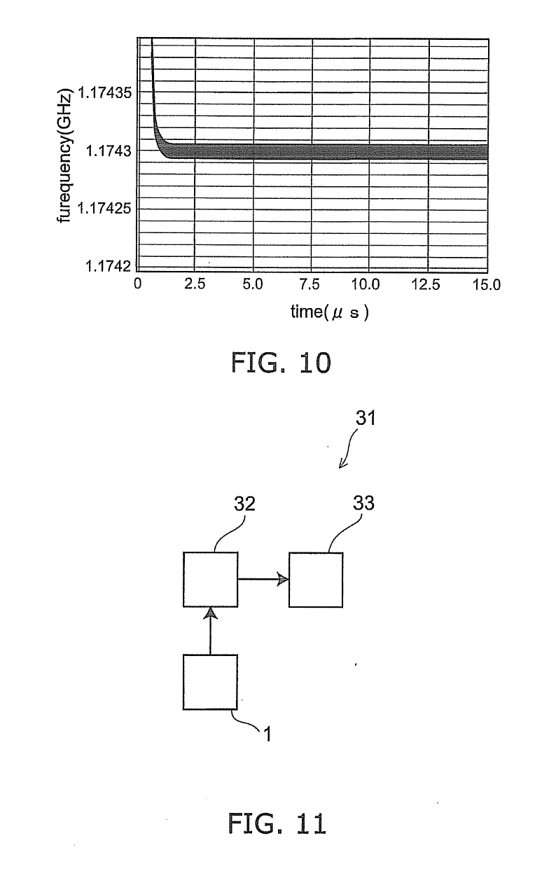

FIG. 10 is a characteristic diagram showing the oscillation frequency of the oscillator shown in FIG. 1.

From the application of the power supply voltage VDD at time=0 μs, the drain voltage of the first transistors 13, 14 immediately reaches the steady state, and the oscillation frequency is stabilized within a short time.

Thus, the oscillator 1 according to this embodiment can reduce the time required for the oscillation frequency to be stabilized.

In the case illustrated in FIG. 1, there is one frequency correction circuit 8. However, an arbitrary number of frequency correction circuits may be connected in parallel. Furthermore, in the illustrated configuration, the frequency correction circuit 8 includes a pair of first capacitors 11, 12 and a pair of first transistors 13, 14. However, the frequency correction circuit may include an arbitrary number of first capacitors and first transistors.

Furthermore, in FIG. 1, the drains of the first transistors 13, 14 of the frequency correction circuit 8 are each biased at approximately half the power supply voltage VDD. To use the first transistors 13, 14 as switching elements, the DC potential of one of the drain and the source needs to be fixed.

However, the potential of both ends, i.e., drain and source, of the first transistors 13, 14 is varied with the signal at both ends 9, 10 of the resonant circuit 2 during the oscillating operation of the oscillator 1, and is not fixed alternatingly. For instance, capacitors may be inserted between the drain of the first transistors 13, 14 and both ends 9, 10 of the resonant circuit 2, respectively. Resistors may be connected between each source and the ground GND. Thus, the potential of the source may be fixed directly.

FIG. 11 is a circuit diagram illustrating a configuration of an electronic device according to a second embodiment.

As shown in FIG. 11, the electronic device 31 includes an oscillator 1, a control circuit 32, and a storage circuit 33.

The oscillator 1 is the oscillator 1 shown in FIG. 1, and supplies clock signal to the control circuit 32.

The control circuit 32 controls writing and reading of the storage circuit 33.

The storage circuit 33 is a circuit for storing digital data, and composed of storage elements such as RAM and ROM.

In the oscillator 1, the time required for the oscillation frequency to be stabilized is short. Thus, the electronic device 31 can reduce power consumption by using a sleep mode even when fast response is required. Furthermore, the electronic device 31 can be integrated in a semiconductor substrate and is also suitable for downsizing. The storage circuit 33 may be configured as a device separate from the device including the oscillator 1 and the control circuit 32. For instance, the storage circuit 33 may be configured as an IC card, and the oscillator 1 and the control circuit 32 may be used to configure a card reader.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An oscillator comprising:
a resonant circuit including one end, one other end, and a frequency correction circuit; and
an amplifier circuit connected in parallel with the resonant circuit, the amplifier circuit configured to amplify a signal at the one end and to output to the one other end,
the frequency correction circuit including:
a first capacitor; and
a first transistor connected in series with the first capacitor so that potentials of both ends of the first transistor are variable.

2. The oscillator according to claim 1, wherein potential of one of both ends of the first capacitor is fixed.

3. The oscillator according to claim 1, wherein one of the both ends of the first transistor is biased.

4. The oscillator according to claim 3, wherein the end of the first transistor not biased varies with potentials of both ends of the resonant circuit.

5. The oscillator according to claim 1, wherein one end of the first capacitor is connected to ground.

6. The oscillator according to claim 1, wherein the first transistor is connected between the resonant circuit and the first capacitor.

7. The oscillator according to claim 1, wherein the first transistor is an n-channel MOSFET.

8. The oscillator according to claim 7, wherein a back gate of the first transistor is connected to ground.

9. The oscillator according to claim 7, wherein a gate of the first transistor is inputted with a low level or high level control signal.

10. The oscillator according to claim 1, wherein the first capacitor has a metal-insulator-metal (MIM) structure.

11. The oscillator according to claim 1, wherein the resonant circuit includes an inductor and a resonant capacitor.

12. The oscillator according to claim 11, wherein the resonant capacitor has a metal-insulator-metal (MIM) structure.

13. The oscillator according to claim 11, wherein the inductor is a spiral inductor.

14. The oscillator according to claim 1, wherein the amplifier circuit includes a pair of n-channel MOSFETs.

15. The oscillator according to claim 1, wherein the amplifier circuit includes a pair of p-channel MOSFETs.

16. An electronic device comprising:
a storage circuit configured to store digital data;
a control circuit configured to control writing and reading of the storage circuit; and
an oscillator configured to supply a clock signal to the control circuit,
the oscillator including:
a resonant circuit including one end, one other end, and a frequency correction circuit; and
an amplifier circuit connected in parallel with the resonant circuit, the amplifier circuit configured to amplify a signal at the one end and to output to the one other end,
the frequency correction circuit including:
a first capacitor; and
a first transistor connected in series with the first capacitor so that potentials of both ends of the first transistor are variable.

17. The device according to claim 16, wherein potential of one of both ends of the first capacitor is fixed.

18. The device according to claim 16, wherein one of the both ends of the first transistor is biased.

19. The device according to claim 16, wherein one end of the first capacitor is connected to ground.

20. The device according to claim 16, wherein the first transistor is connected between the resonant circuit and the first capacitor.
